(19) United States
(12) Patent Application Publication
(10) Pub. No.: US 2011/0101506 A1
(43) Pub. Date: May 5, 2011

(54) Stress Memorization Technique Using Silicon Spacer

(75) Inventors: Shahid A. Butt, Hopewell Junction, NY (US); Viorel Ontalus, Hopewell Junction, NY (US); Robert R. Robison, Essex Junction, VT (US)

(73) Assignee: International Business Machines Corporation, Armonk, NY (US)

(21) Appl. No.: 12/608,107

(22) Filed: Oct. 29, 2009

(51) Int. Cl. H01L 29/06; H01L 21/31; H01L 23/58

(52) U.S. Cl. 257/632; 438/778; 257/798; 257/E29.006; 257/E21.24; 257/E23.002

(57) ABSTRACT

A structure for memorizing tensile stress in a semiconductor device includes a gate electrode of the semiconductor device; a silicon spacer adjacent to the gate electrode; and a capping layer encapsulating the gate electrode and the silicon spacer, wherein the silicon spacer and capping layer are configured to cause a tensile stress to be memorized in the gate electrode during an annealing process. A method for memorizing tensile stress in a semiconductor device includes forming a silicon spacer adjacent to a gate electrode of the semiconductor device; forming a capping layer over the silicon spacer and the gate electrode; and annealing the semiconductor device, wherein the silicon spacer and capping layer cause a tensile stress to be memorized in the gate electrode during annealing. A disposable silicon spacer is configured to induce a tensile stress in a semiconductor device during a stress memorization technique process.

### FIELD

This disclosure relates generally to the field of semiconductor fabrication.

### DESCRIPTION OF RELATED ART

Inducing elevated stress in semiconductor material may increase electron or hole mobility of the material, allowing for higher conductivity in a semiconductor device. In particular, negative channel field effect transistor (NFET) metal oxide semiconductor (MOS) transistor performance may be enhanced by stress memorization technique (SMT). In SMT, a capping layer, preferably high-tensile, is formed over a gate electrode region of an n-type field effect transistor (NFET), the transistor is annealed, (i.e., the transistor is heated to a high temperature, which may be over 1000° C. in some embodiments, and then cooled), and the capping layer is removed. The capping layer expands less than the gate electrode during annealing; therefore, the capping layer induces stress in the gate electrode and in the transistor channel at high temperatures, and the stress is memorized (i.e., permanently induced) in the gate electrode and channel during cooling.

### SUMMARY

In one aspect, a structure for memorizing tensile stress in a semiconductor device includes a gate electrode of the semiconductor device; a silicon spacer adjacent to the gate electrode; and a capping layer encapsulating the gate electrode and the silicon spacer, wherein the silicon spacer and capping layer are configured to cause a tensile stress to be memorized in the gate electrode during an annealing process.

In one aspect, a method for memorizing tensile stress in a semiconductor device includes forming a silicon spacer adjacent to a gate electrode of the semiconductor device; forming a capping layer over the silicon spacer and the gate electrode; and annealing the semiconductor device, wherein the silicon spacer and capping layer cause a tensile stress to be memorized in the gate electrode during annealing.

In one aspect, a disposable silicon spacer is configured to induce a tensile stress in a semiconductor device during a stress memorization technique process.

Additional features are realized through the techniques of the present exemplary embodiment. Other embodiments are described in detail herein and are considered a part of what is claimed. For a better understanding of the features of the exemplary embodiment, refer to the description and to the drawings.

### BRIEF DESCRIPTION OF THE SEVERAL VIEWS OF THE DRAWINGS

Referring now to the drawings wherein like elements are numbered alike in the several FIGURES:

FIG. 1 illustrates an embodiment of a semiconductor device comprising a silicon spacer.

FIG. 2 illustrates an embodiment of a semiconductor device comprising a silicon spacer after formation of a nitride capping layer.

FIG. 3 illustrates an embodiment of a semiconductor device after removal of the nitride capping layer and removal of the silicon spacer.

FIG. 4 illustrates an embodiment of a semiconductor device after formation of a spacer.

FIG. 5 illustrates an embodiment of a method for SMT using a silicon spacer.

### DETAILED DESCRIPTION

Embodiments of systems and methods for SMT using a silicon spacer are provided, with exemplary embodiments being discussed below in detail. Formation of a silicon spacer on a semiconductor device before the SMT process is performed maximizes the memorized stress in the device, due to the relatively high expansion of silicon at high temperatures. The silicon spacer may be disposable, i.e., the silicon spacer may be removed after annealing is completed and replaced with another spacer, which may be made from a different material. Stress in the semiconductor channel may be increased by over 25% compared to a standard SMT process, leading to a mobility gain of about 2% to about 8% in some embodiments.

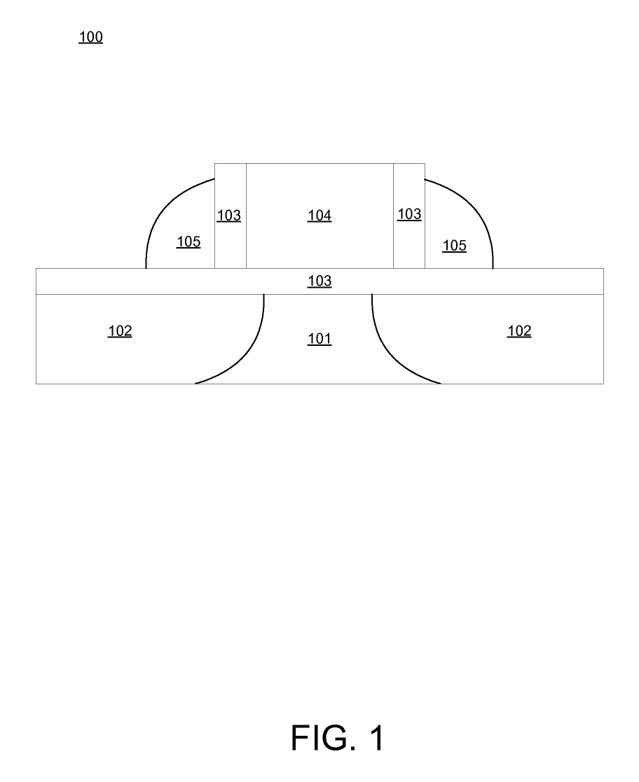

FIG. 1 illustrates an embodiment of a semiconductor device 100 comprising a silicon spacer 105. Semiconductor device 100 comprises silicon transistor substrate regions 101 and 102; region 101 comprises a transistor channel comprising a p-type material, and source/drain regions 102 comprise n-type material. Semiconductor device 100 further comprises a gate electrode, comprising gate regions 103 and 104. Gate regions 103 comprise oxide or high-K material in some embodiments. Gate region 104 may comprise amorphous silicon or polycrystalline silicon material in some embodiments. The silicon spacer 105 may comprise amorphous silicon or polycrystalline silicon material in some embodiments.

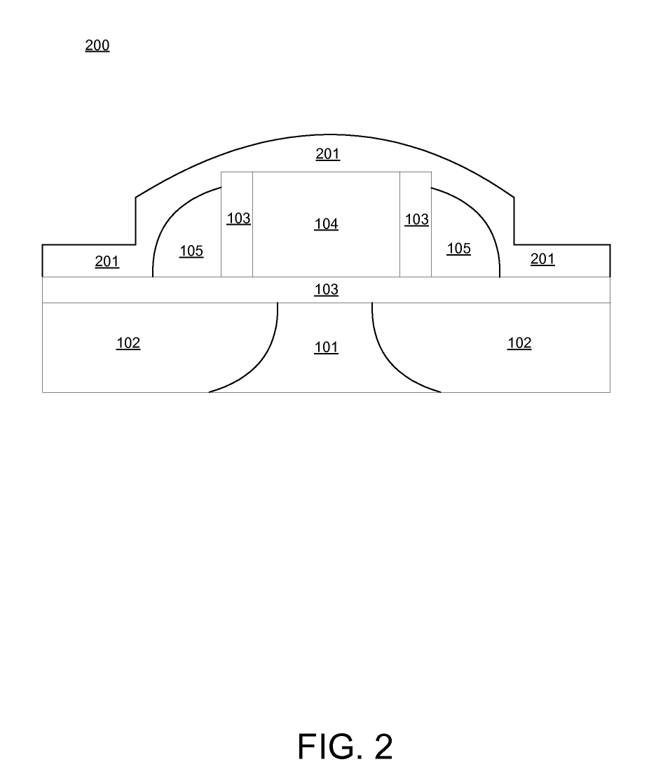

FIG. 2 illustrates an embodiment of a semiconductor device 200 comprising a silicon spacer 105 after formation of a capping layer 201. Capping layer 201 encapsulates silicon spacer 105 and gate regions 103 and 104. Capping layer 201 may comprise nitride or oxide in some embodiments. Annealing is performed on semiconductor device 100 after formation of capping layer 201; during annealing, capping layer 201 expands less than silicon spacer 105 and gate region 104, and expansion of silicon spacer 105 and gate region 104 is trapped by capping layer 201. Tensile stress is thereby induced in gate electrode region 104 and channel 101. During the cooling portion of the annealing process, the tensile stress is memorized by gate electrode region 104 and channel 101.

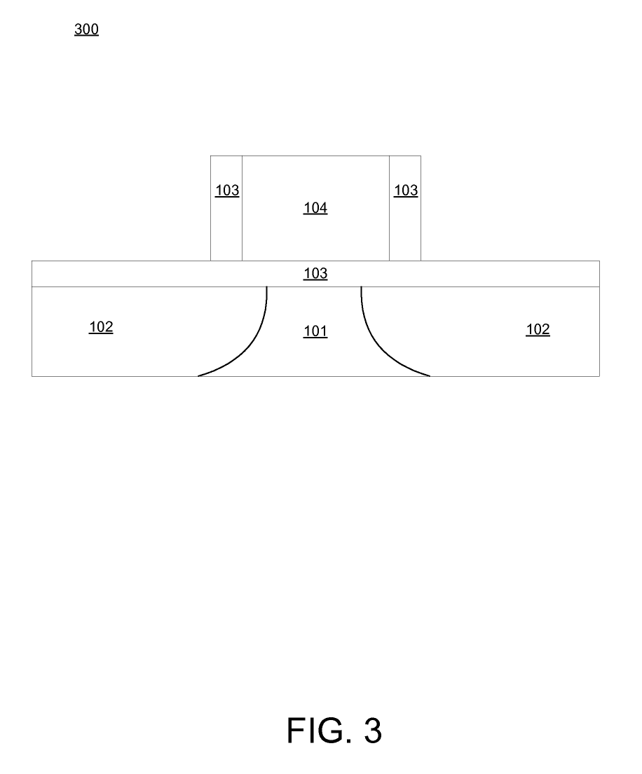

FIG. 3 illustrates an embodiment of a semiconductor device 300 after completion of annealing and removal of capping layer 201 and silicon spacer 105. The capping layer 201 may be removed by any appropriate method, including but not limited to application of hot phosphorus. The silicon spacer 105 may be removed by any appropriate method, including but not limited to reactive ion etching (RIE). The stress induced in gate region 104 and channel 101 during annealing is memorized by gate region 104 and channel 101, increasing the conductivity of gate region 104 and channel 101.

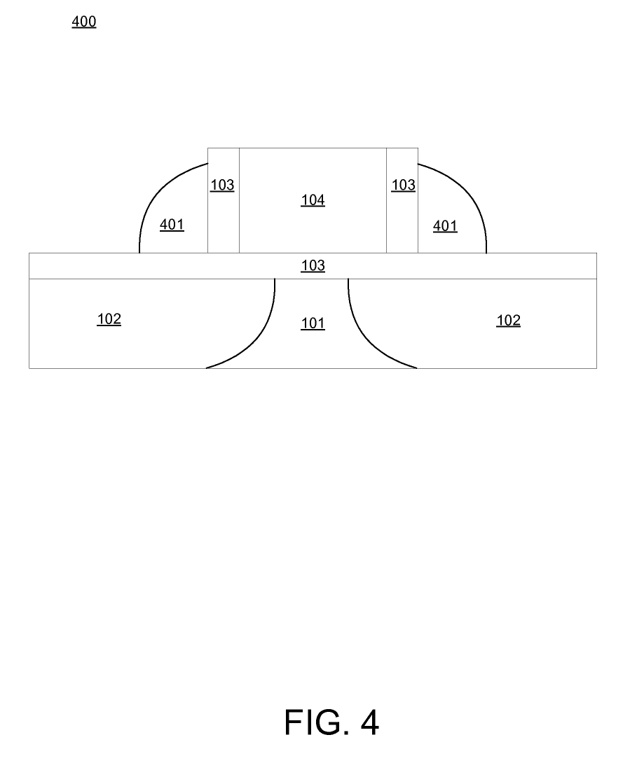

FIG. 4 illustrates an embodiment of a semiconductor device 400 after formation of a spacer 401. Spacer 401 may comprise nitride or oxide in some embodiments.

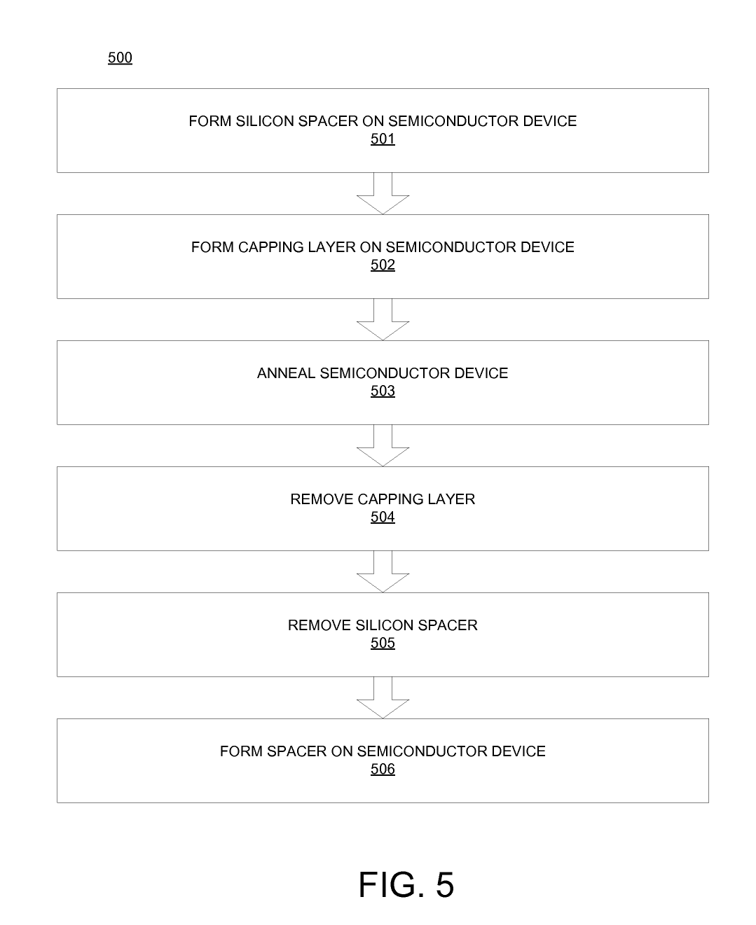

FIG. 5 illustrates an embodiment of a method 500 for SMT using a silicon spacer. In block 501, a silicon spacer is formed on a semiconductor device. The silicon spacer may comprise amorphous silicon or polycrystalline silicon material in some embodiments. In block 502, a capping layer is formed over the silicon spacer and a gate electrode of the semiconductor device. The capping layer may comprise nitride or oxide in some embodiments. In block 503, the semiconductor device is annealed. The annealing process may reach temperatures of over 1000° C. in some embodiments. During annealing, the silicon spacer and gate electrode expand; this expansion is trapped by the capping layer, inducing stress that is memorized in the gate electrode and in a channel of the semiconductor device during cooling, increasing the conductivity of the gate electrode and the channel. In block 504, the capping layer is removed. The capping layer may be removed by any appropriate method, including but not limited to application of hot phosphorus. In block 505, the silicon spacer is removed. The silicon spacer may be removed by any appropriate method, including but not limited to RIE. In block 506, a spacer is formed on the semiconductor device. The spacer may comprise nitride or oxide in some embodiments.

The technical effects and benefits of exemplary embodiments include increased tensile stress in semiconductor material, resulting in increased conductivity.

The terminology used herein is for the purpose of describing particular embodiments only and is not intended to be limiting of the invention. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A structure for memorizing tensile stress in a semiconductor device, comprising:
a gate electrode of the semiconductor device;
a silicon spacer adjacent to the gate electrode; and
a capping layer encapsulating the gate electrode and the silicon spacer, wherein the silicon spacer and capping layer are configured to cause a tensile stress to be memorized in the gate electrode during an annealing process.

2. The structure of claim 1, further comprising a channel region of the semiconductor device.

3. The structure of claim 2, wherein a tensile stress is memorized by the channel region during the annealing process.

4. The structure of claim 1, wherein the silicon spacer comprises polycrystalline silicon.

5. The structure of claim 1, wherein the silicon spacer comprises amorphous silicon.

6. The structure of claim 1, wherein the capping layer comprises nitride.

7. The structure of claim 1, wherein the capping layer comprises oxide.

8. A method for memorizing tensile stress in a semiconductor device, the method comprising:
forming a silicon spacer adjacent to a gate electrode of the semiconductor device;
forming a capping layer over the silicon spacer and the gate electrode; and
annealing the semiconductor device, wherein the silicon spacer and capping layer cause a tensile stress to be memorized in the gate electrode during annealing.

9. The method of claim 8, further comprising memorizing a tensile stress in a channel region of the semiconductor device during annealing.

10. The method of claim 8, wherein the silicon spacer comprises polycrystalline silicon.

11. The method of claim 8, wherein the silicon spacer comprises amorphous silicon.

12. The method of claim 8, wherein the capping layer comprises nitride.

13. The method of claim 8, wherein the capping layer comprises oxide.

14. The method of claim 8, further comprising removing the capping layer after annealing.

15. The method of claim 14, further comprising removing the silicon spacer.

16. The method of claim 15, further comprising replacing the silicon spacer with a second spacer.

17. The method of claim 17, wherein the second spacer comprises nitride.

18. The method of claim 17, wherein the second spacer comprises oxide.

19. A disposable silicon spacer, the disposable silicon spacer configured to induce a tensile stress in a semiconductor device during a stress memorization technique (SMT) process.

20. The disposable silicon spacer of claim 19, wherein the disposable silicon spacer is located adjacent to a gate electrode of the semiconductor device.
